(19) United States
(12) Patent Application Publication
(10) Pub. No.: US 2025/0293058 A1
(43) Pub. Date: Sep. 18, 2025

(54) SEPARATING APPARATUS AND SEPARATING METHOD

(71) Applicant: Tokyo Electron Limited, Tokyo (JP)

(72) Inventors: Kei TASHIRO, Koshi City, Kumamoto (JP); Mitsutoshi TOMITA, Koshi City, Kumamoto (JP)

(73) Assignee: Tokyo Electron Limited, Tokyo (JP)

(21) Appl. No.: 19/080,771

(22) Filed: Mar. 14, 2025

(30) Foreign Application Priority Data
Mar. 15, 2024 (JP) 2024-041659

(51) Int. Cl. H01L 21/67; H01L 21/304; H01L 21/683

(52) U.S. Cl. CPC H01L 21/67092; H01L 21/3043; H01L 21/67259; H01L 21/6836; H01L 2221/68327

(57) ABSTRACT

A separating apparatus separates a combined substrate in which a first substrate and a second substrate are bonded to each other. The separating apparatus includes a holder that holds the combined substrate and rotates the combined substrate in a circumferential direction, a separation inducing device which is equipped with a blade and forms a groove portion by inserting the blade between the first substrate and the second substrate from a side of the combined substrate held by the holder, and control circuitry that controls the holder and the separation inducing device to form the groove portion longer than a longitudinal length of the blade along the circumferential direction of the combined substrate.

### CROSS-REFERENCE TO RELATED APPLICATION

This application claims the benefit of Japanese Patent Application No. 2024-041659 filed on Mar. 15, 2024, the entire disclosure of which is incorporated herein by reference.

### TECHNICAL FIELD

The exemplary embodiments described herein pertain generally to a separating apparatus and a separating method.

### BACKGROUND

Patent Document 1 discloses a separating apparatus that separates two substrates (a target substrate and a support substrate) constituting a combined substrate. In the separating apparatus, the target substrate is held by a first holder provided on a lower side and the support substrate is held by a second holder provided on an upper side, and a blade is allowed to penetrate between the target substrate and the support substrate, which triggers separation. Also, the second holder moves a plurality of movable attraction units each having an attraction pad downwards to attract the support substrate, and as the support substrate is raised from the movable attraction units on an entry side of the blade, the target substrate and the support substrate are separated from the blade side.

### PRIOR ART DOCUMENT

Patent Document 1: Japanese Patent Laid-open Publication No. 2015-207776.

### SUMMARY

In one exemplary embodiment, a separating apparatus, configured to separate a combined substrate in which a first substrate and a second substrate are bonded to each other, includes: a holder configured to hold the combined substrate and rotate the combined substrate in a circumferential direction; a separation inducing device equipped with a blade and configured to form a groove portion by inserting the blade between the first substrate and the second substrate from a side of the combined substrate held by the holder; and a control device. The control device controls the holder and the separation inducing device to form the groove portion longer than a longitudinal length of the blade along the circumferential direction of the combined substrate.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numerals in different figures indicates similar or identical items.

FIG. 1 is a plan view schematically illustrating a configuration of a separating system according to an exemplary embodiment;

FIG. 2 is a side view schematically illustrating a configuration of a delivery station of the separating system;

FIG. 3A is a cross-sectional side view of a combined substrate, a dicing frame, and a dicing tape, and FIG. 3B is a plan view of the combined substrate, the dicing frame, and the dicing tape;

FIG. 4 is a partial cross-sectional side view schematically illustrating a configuration of a separating apparatus according to the exemplary embodiment;

FIG. 5 is a plan view of a support member, an upper attraction group, and a blade;

FIG. 6A is a first diagram showing one of a series of processes of separating the combined wafer, FIG. 6B is a second diagram showing one of the series of processes of separating the combined wafer, FIG. 6C is a third diagram showing one of the series of processes of separating the combined wafer, and FIG. 6D is a fourth diagram showing one of the series of processes of separating the combined wafer;

FIG. 7A is a plan view illustrating an example where a groove portion is formed, and FIG. 7B is a plan view illustrating an example where a plurality of groove portions is formed;

FIG. 8A to FIG. 8F are partial cross-sectional side views showing a sequence of insertion operations, and FIG. 8G is a plan view schematically illustrating an operation of changing a position in a circumferential direction;

FIG. 9 is a flowchart illustrating a separating method according to the exemplary embodiment;

FIG. 10A is a plan view illustrating a groove portion formed by a separating method according to a first modification example, FIG. 10B is a plan view illustrating a groove portion formed by a separating method according to a second modification example, and FIG. 10C is a plan view illustrating a groove portion formed by a separating method according to a third modification example; and

FIG. 11A is a plan view illustrating a groove portion formed by a separating method according to a fourth modification example, and FIG. 11B is a plan view illustrating a groove portion formed by a separating method according to a fifth modification example.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, exemplary embodiments of the present disclosure will be described with reference to the accompanying drawings. In the various drawings, same parts will be assigned same reference numerals, and redundant description will be omitted. Further, the X-axis direction, the Y-axis direction, and the Z-axis direction used in the following description are axis directions perpendicular to each other. The X-axis direction and the Y-axis direction are horizontal directions, and the Z-axis direction is a vertical direction.

### <Configuration of Separating System 100>

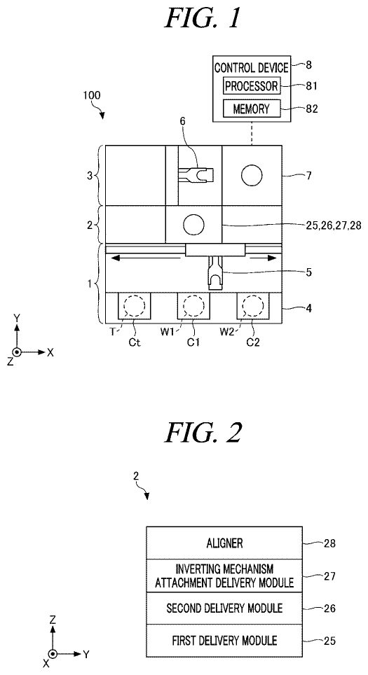

First, a configuration of a separating system 100 according to an exemplary embodiment of the present disclosure will be described with reference to FIG. 1 and FIG. 2. The separating system 100 includes a separating apparatus 7 configured to separate a combined substrate T in which a first substrate W1 and a second substrate W2 are bonded to each other. In the separating system 100, the combined substrate T is carried into the separating apparatus 7, and then separated in the separating apparatus 7, and each of the separated first and second substrates W1 and W2 is carried out of the separating apparatus 7.

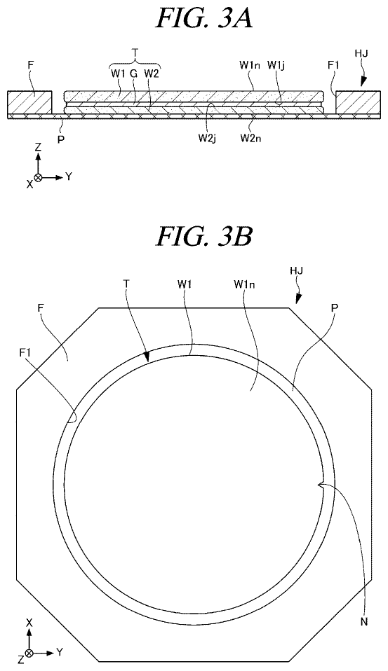

The first substrate W1 and the second substrate W2 constituting the combined substrate T are formed into circular plates having substantially the same shape (same diameter). Hereinafter, as shown in FIG. 3A, the first substrate W1 may sometimes be referred to as “upper wafer W1”; the second substrate W2, “lower wafer W2”; and the combined substrate T, “combined wafer T”. Also, hereinafter, among plate surfaces of the upper wafer W1, the plate surface to be bonded to the lower wafer W2 will be referred to as “bonding surface W1j”, and the plate surface opposite to the bonding surface W1j will be referred to as “non-bonding surface W1n”. Likewise, among plate surfaces of the lower wafer W2, the plate surface to be bonded to the upper wafer W1 will be referred to as “bonding surface W2j”, and the plate surface opposite to the bonding surface W2j will be referred to as “non-bonding surface W2n”. Further, the combined wafer T, the upper wafer W1, and the lower wafer W2 may have a shape (e.g., a polygonal shape) other than a circular shape.

At least one of the upper wafer W1 and the lower wafer W2 is a substrate on which a plurality of electronic circuits is formed on a semiconductor substrate, such as a silicon wafer or a compound semiconductor wafer. The compound semiconductor wafer may be, for example, a GaAs wafer, a SiC wafer, a GaN wafer, or an InP wafer. One of the upper wafer W1 and the lower wafer W2 may be a bare wafer on which no electronic circuit is formed.

In the combined wafer T according to the example shown in FIG. 3A, a support substrate is used as the upper wafer W1 and a silicon wafer on which electronic circuits are formed is used as the lower wafer W2. In this case, the support substrate (the upper wafer W1) has a greater thickness than the lower wafer W2. A material of the support substrate (the upper wafer W1) is not particularly limited, but may include silicon or quartz.

The bonding surface W1j of the upper wafer W1 is bonded to the bonding surface W2j of the lower wafer W2 by an adhesive G. The type of the adhesive G is not particularly limited, and an appropriate resin material may be selected depending on a material of the upper wafer W1 and a material of the lower wafer W2. Alternatively, the upper wafer W1 and the lower wafer W2 may be chemically bonded to each other. For example, the surfaces (the bonding surfaces W1j and W2j) of the upper wafer W1 and the lower wafer W2 are plasma-processed to be modified, and the modified surfaces are hydrophilized with pure water, and, thus, the surfaces are bonded to each other by a Van der Waals force and a hydrogen bond (intermolecular force).

Also, as shown in FIG. 3B, the combined wafer T has a notch N in a part of an outer edge in a circumferential direction. For example, the notch N is formed by cutting off each of outer edges of the upper wafer W1 and the lower wafer W2. The upper wafer W1 and the lower wafer W2 are bonded to each other such that the notch N of the upper wafer W1 is aligned with the notch N of the lower wafer W2.

As shown in FIG. 3A and FIG. 3B, the combined wafer T according to the exemplary embodiment is held by a holding jig HJ including a dicing frame F and a dicing tape P. The dicing frame F is an annular metal member provided with an inner opening F1 having a greater diameter than the combined wafer T. The dicing frame F has a greater thickness than the combined wafer T. The dicing tape P is formed of an elastically deformable resin material having flexibility, and an adhesive layer is formed on its one surface (upper surface). When a peripheral portion of the dicing tape P is attached to a rear surface of the dicing frame F, the opening F1 of the dicing frame F is closed. Also, within the opening F1 of the dicing frame F, a rear surface of the combined wafer T is fixed to the one surface of the dicing tape P. Specifically, the non-bonding surface W2n of the lower wafer W2 is attached to the adhesive layer of the dicing tape P. The dicing tape P has sufficient flexibility to displace the combined wafer T and the dicing frame F relative to each other in a thickness direction.

Referring back to FIG. 1, the separating system 100 is equipped with a carry-in/out station 1, a delivery station 2, and a processing station 3. The carry-in/out station 1, the delivery station 2, and the processing station 3 are configured as separable units and arranged in this order toward the positive Y-axis direction.

The carry-in/out station 1 performs the carry-in of the combined wafer T and the carry-out of the separated upper wafer W1 and the separated lower wafer W2. The carry-in/out station 1 is equipped with a mounting device 4 and a first transfer device 5.

The mounting device 4 includes a plurality of (three in FIG. 1) cassette mounting tables configured to mount thereon a cassette, such as a Front-Opening Unified Pod (FOUP), capable of accommodating a plurality of substrates. Cassettes to be mounted on the respective cassette mounting tables may include a cassette Ct capable of accommodating the combined wafer T, a cassette C1 capable of accommodating the separated upper wafer W1, and a cassette C2 capable of accommodating the separated lower wafer W2.

The first transfer device 5 is disposed adjacent to the mounting device 4 in the positive Y-axis direction, and serves to transfer the combined wafer T, the upper wafer W1, and the lower wafer W2. The first transfer device 5 is equipped with, for example, a base and a plurality of transfer arms, and serves to move a substrate held by the transfer arm in the horizontal direction and the vertical direction and pivot the substrate around a vertical axis of the base. The first transfer device 5 is an example of a substrate transfer device.

In the carry-in/out station 1, the first transfer device 5 transfers the combined wafer T from each cassette Ct to the delivery station 2, and transfers the separated upper wafer W1 and the separated lower wafer W2 from the delivery station 2 to the respective cassettes C1 and C2.

The delivery station 2 delivers the combined wafer T before the separation, and the separated upper wafer W1 and the separated lower wafer W2. As shown in FIG. 2, the delivery station 2 is equipped with, for example, a first delivery module 25, a second delivery module 26, an inverting mechanism attachment delivery module 27, and an aligner 28. The first delivery module 25, the second delivery module 26, the inverting mechanism attachment delivery module 27, and the aligner 28 are arranged in this order toward a vertically upward direction (positive Z-axis direction).

The combined wafer T transferred from the carry-in/out station 1 is disposed in the first delivery module 25. The combined wafer T disposed in the first delivery module 25 is transferred to the processing station 3 by a second transfer device 6 which will be described later.

The separated lower wafer W2 is disposed in the second delivery module 26. The separated lower wafer W2 disposed in the second delivery module 26 is transferred to the carry-in/out station 1 by the first transfer device 5.

The separated upper wafer W1 is disposed in the inverting mechanism attachment delivery module 27. The inverting mechanism attachment delivery module 27 is equipped with an inverting mechanism (not shown) configured to invert the separated upper wafer W1. The separated upper wafer W1 disposed in the inverting mechanism attachment delivery module 27 is inverted by the inverting mechanism, and then transferred to the carry-in/out station 1 by the first transfer device 5.

The aligner 28 aligns some or all of the combined wafer T, the separated upper wafer W1, and the separated lower wafer W2. For example, when the aligner 28 aligns the combined wafer T, the aligner 28 holds and rotates the combined wafer T and detects a position of the notch N (see FIG. 3B) of the combined wafer T being rotated to calculate an eccentric amount of the combined wafer T. The separating system 100 operates the aligner 28, the first transfer device 5 or the second transfer device 6 appropriately based on the eccentric amount, and adjusts an orientation of the combined wafer T in the horizontal direction. The same applies to a case where the aligner 28 aligns the upper wafer W1 and the lower wafer W2.

The processing station 3 is equipped with the second transfer device 6 and the separating apparatus 7, and separates the combined wafer T into the upper wafer W1 and the lower wafer W2. For example, the second transfer device 6 and the separating apparatus 7 are arranged along the X-axis direction in the processing station 3.

The second transfer device 6 transfers the combined wafer T, the separated upper wafer W1, and the separated lower wafer W2 between the delivery station 2 and the separating apparatus 7. The second transfer device 6 is equipped with, for example, a base and a plurality of transfer arms, and serves to move a substrate held by the transfer arm in the horizontal direction and the vertical direction and pivot the substrate around the vertical axis of the base. The second transfer device 6 is an example of a substrate transfer device.

In the processing station 3, the second transfer device 6 performs the carry-in of the combined wafer T from the delivery station 2 to the separating apparatus 7. Also, in the processing station 3, the second transfer device 6 separately performs a carry-out processing to transfer the separated lower wafer W2 from the separating apparatus 7 to the delivery station 2 and a carry-out processing to transfer the separated upper wafer W1 from the separating apparatus 7 to the delivery station 2.

The separating apparatus 7 separates the combined wafer T transferred by the second transfer device 6 into the upper wafer W1 and the lower wafer W2. The detailed configuration and operation of the separating apparatus 7 will be described below.

Also, the separating system 100 is equipped with a control device 8 configured to control an operation of the separating system 100. The control device 8 is a computer equipped with a processor 81, a memory 82, a non-illustrated input/output interface. The processor 81 includes one or a combination of two or more of a central processing unit (CPU), a graphics processing unit (GPU), an application specific integrated circuit (ASIC), a field-programmable gate array (FPGA), a circuit including a plurality of discrete semiconductors, and the like. The memory 82 includes a non-volatile memory and a volatile memory. The memory 82 stores a program that controls various processings, and the processor 81 controls an operation of the separating system 100 by reading and executing the program stored in the memory 82. In other words, the control device 8 in the present disclosure is an electronic circuit including CPU, GPU, ASIC, FPGA, etc., and is configured to execute instruction codes stored in the memory 82 or designed for special purposes to perform various control operations described in the present disclosure. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The separating system 100 first takes out the combined wafer T from the cassette Ct placed in the mounting device 4 by the first transfer device 5 of the carry-in/out station 1 and places the combined wafer T in the first delivery module 25 of the delivery station 2 under the control of the control device 8. Then, the separating system 100 takes out the combined wafer T placed in the first delivery module 25 by the second transfer device 6 of the processing station 3 and carries the combined wafer T into the aligner 28. The control device 8 controls the aligner 28 to calculate an eccentric amount of the combined wafer T and adjusts a reception position of the combined wafer T (an orientation of the combined wafer T in the horizontal direction) where the second transfer device 6 receives the combined wafer T, based on the eccentric amount. Further, the separating system 100 carries the combined wafer T from the aligner 28 into the separating apparatus 7 by the second transfer device 6.

Furthermore, the separating apparatus 7 separates the combined wafer T into the upper wafer W1 and the lower wafer W2 under the control of the control device 8. Also, the separating apparatus 7 may be equipped with a dedicated control substrate and may control the separation of the combined wafer T under the control of the control substrate based on a command from the control device 8.

After the separation by the separating apparatus 7, the separating system 100 operates the second transfer device 6 to transfer the lower wafer W2 from the separating apparatus 7 to the aligner 28, and the aligner 28 adjusts an orientation of the lower wafer W2 in the horizontal direction. Then, the lower wafer W2 is transferred to the second delivery module 26. Also, in the separating system 100, the first transfer device 5 takes out the lower wafer W2 from the second delivery module 26, and the cassette C2 placed in the carry-in/out station 1 accommodates therein the lower wafer W2. When a predetermined number of lower wafers W2 are accommodated in the cassette C2, the cassette C2 is taken out from the carry-in/out station 1.

Further, the separating system 100 operates the second transfer device 6 to transfer the upper wafer W1 from the separating apparatus 7 to the aligner 28 at a timing different from the timing of transferring the lower wafer W2, and the aligner 28 adjusts an orientation of the upper wafer W1 in the horizontal direction. Then, the upper wafer W1 is transferred to the inverting mechanism attachment delivery module 27. Furthermore, in the separating system 100, the inverting mechanism of the inverting mechanism attachment delivery module 27 inverts the upper wafer W1. Thus, the bonding surface W1j of the upper wafer W1 faces upwards. Thereafter, in the separating system 100, the first transfer device 5 takes out the upper wafer W1 from the inverting mechanism attachment delivery module 27, and the cassette C1 placed in the carry-in/out station 1 accommodates therein the upper wafer W1. When a predetermined number of upper wafers W1 are accommodated in the cassette C1, the cassette C1 is taken out from the carry-in/out station 1.

### <Configuration of Separating Apparatus 7>

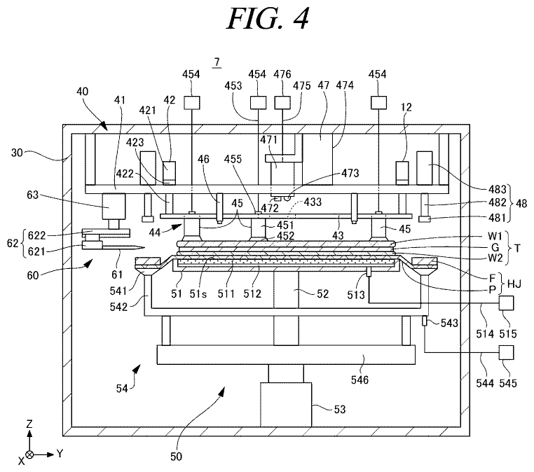

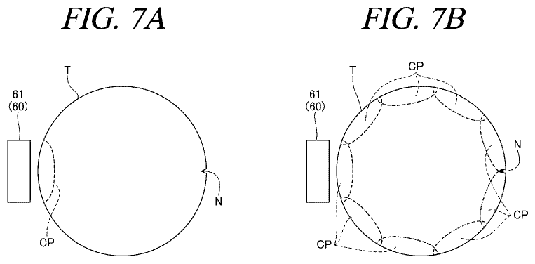

Then, a configuration of the separating apparatus 7 according to the exemplary embodiment will be described with reference to FIG. 4. The separating apparatus 7 holds and interposes therein the combined wafer T along the vertical direction (Z-axis direction) and separates the upper wafer W1 and the lower wafer W2 of the combined wafer T. The separating apparatus 7 includes a processing container 30 into which the combined wafer T is carried, and is equipped with an attraction separation device 40, a holder 50, and a separation inducing device 60 within the processing container 30. The separation inducing device 60 forms a groove portion CP (see FIG. 7A and FIG. 7B) for separation of the combined wafer T into the upper wafer W1 and the lower wafer W2.

The attraction separation device 40 performs a separating operation of attracting the non-bonding surface W1n of the upper wafer W1 in the combined wafer T to hold the upper wafer W1 and pulling the upper wafer W1 vertically upwards. The attraction separation device 40 includes a base member 41, a pair of (i.e., two) elevating mechanisms 42 provided on the base member 41, a support member 43 supported by the pair of elevating mechanisms 42, and an upper attraction group 44 supported by the support member 43 and configured to attract the upper wafer W1. Also, the attraction separation device 40 is equipped with a delivery holder 47 operated to deliver the separated upper wafer W1 to a transfer device (not shown) and a pressing device 48 configured to press the dicing frame F.

The base member 41 is a plate member having an appropriate thickness, and is directly or indirectly fixed to, for example, a ceiling wall (or a side wall) of the processing container 30. The base member 41 has sufficient rigidity to maintain an extended state in the horizontal direction (X- and Y-axis directions) within the processing container 30.

The pair of elevating mechanisms 42 is fixed on the base member 41 and thus located at the same height position. The pair of elevating mechanisms 42 supports the support member 43 located under the base member 41 in the vertical direction, and moves the support member 43 up and down. Each elevating mechanism 42 includes a main body 421, a shaft 422 protruding from the main body 421 vertically downwards, and a load cell 423 configured to detect a load applied to the shaft 422.

The main body 421 is mounted on the base member 41, and includes therein a drive source and a delivery mechanism (all not illustrated) configured to move the shaft 422 along the vertical direction. The main body 421 is connected to the control device 8 and moves the shaft 422 up and down under the control of the control device 8. The separating apparatus 7 can move the shafts 422 of the pair of elevating mechanisms 42 up and down independently of each other.

The shaft 422 linearly extends along the vertical direction, and supports the support member 43 connected to its lower end. The load cell 423 detects the load applied to the shaft 422, and transmits the detection result to the control device 8. When the combined wafer T is separated, the control device 8 controls a height position of the support member 43 based on the detection result from the load cell 423.

The support member 43 is a thin-plate-shaped member, and supports the upper attraction group 44 configured to attract the upper wafer W1. The support member 43 is formed of a metallic material, and has rigidity for supporting the upper attraction group 44 as well as flexibility that enables elastic deformation in the vertical direction. The support member 43 is suspended to cross the pair of elevating mechanisms 42 and extends approximately parallel to an attraction surface 51s of the holder 50 provided thereunder. Therefore, a lower surface of the support member 43 faces the combined wafer T held by the holder 50.

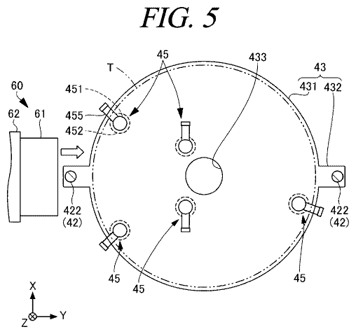

As shown in FIG. 5, the support member 43 includes a circular plate 431 and a pair of fins 432 provided on both sides of the circular plate 431 in the Y-axis direction. The circular plate 431 and the pair of fins 432 are fixed to each other by an appropriate connection mechanism, such as screwing, welding, adhesion, etc. Also, the circular plate 431 may be formed integrally with the pair of fins 432.

The circular plate 431 is formed into a circular shape having the same diameter as the upper wafer W1. The center of the circular plate 431 substantially coincides with the center of the attraction surface 51s of the holder 50. The circular plate 431 overlaps the combined wafer T held by the holder 50 when viewed from the top. The circular plate 431 serves as a component to directly support the upper attraction group 44.

A through hole 433 is formed through a portion including the center of the circular plate 431 in a thickness direction of the circular plate 431. The through hole 433 allows the delivery holder 47 (see FIG. 4) to pass therethrough, and the delivery holder 47 holds the upper wafer W1. Alternatively, the circular plate 431 may include a plurality of holes (not shown) formed through the circular plate 431 in the thickness direction, which makes it easy to elastically deform the circular plate 431. Otherwise, the circular plate 431 may include a plurality of ribs or grooves extending in the X-axis direction along the Y-axis direction, which makes it possible to suppress the elastic deformation of the circular plate 431 in the X-axis direction and promote the elastic deformation of the circular plate 431 in the Y-axis direction.

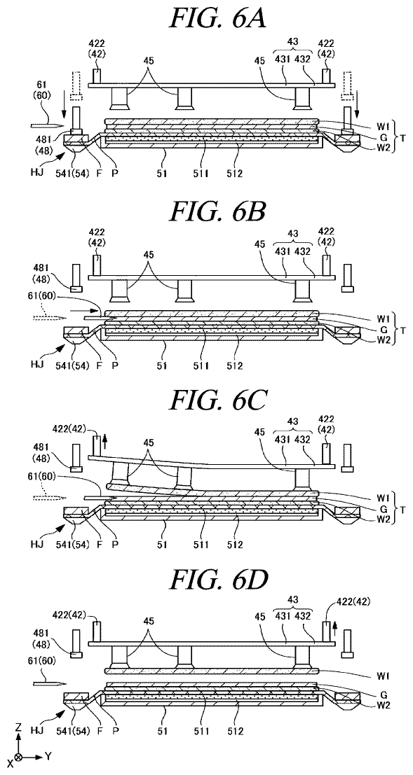

The pair of fins 432 protrudes in opposite directions to each other from an outer edge of the circular plate 431 in the Y-axis direction. The shafts 422 of the elevating mechanisms 42 are connected to ends of the fins 432, respectively. Thus, the fins 432 are moved by the pair of elevating mechanisms 42 in the vertical direction (Z-axis direction). A posture of the circular plate 431 in the horizontal direction varies depending on a height position of each fin 432 (the shaft 422 of the elevating mechanism 42). Particularly, when the elevating mechanisms 42 independently move up and down, the support member 43 is elastically deformed to be bent toward the Y-axis direction to cause the upper attraction group 44 to be bent and displaced (see FIG. 6C).

As shown in FIG. 4 and FIG. 5, the upper attraction group 44 supported by the support member 43 includes a plurality of attraction bodies 45. Each attraction body 45 includes a cylindrical member 451 extending in the vertical direction, a contact member 452 provided at a lower end of the cylindrical member 451, and a suction path 453 connected to the cylindrical member 451. Also, a suction device 454, such as a vacuum pump, is provided in the suction path 453 of each attraction body 45. Further, the attraction paths 453 are joined outside and thus may be connected to the single attraction device 454.

The cylindrical member 451 includes therein a suction space extending in an axial direction. The cylindrical member 451 is tightly connected to the circular plate 431 of the support member 43 and protrudes from the lower surface of the support member 43. When the support member 43 is in the horizontal posture, the cylindrical members 451 place the contact members 452 at the same height position. Also, in the cylindrical member 451, a port 455 connected to the suction path 453 is provided on an upper surface of the support member 43.

The contact member 452 is formed into, for example, a truncated cone shape or a cylindrical shape, and serves as a part in direct contact with the non-bonding surface Win of the upper wafer W1. Desirably, the contact member 452 may be formed of a rubber material or other resin materials. The contact member 452 may be formed to have high rigidity (to suppress elastic deformation). If the contact member 452 is elastically deformed to a significant extent when the attraction separation device 40 is moved up, the attracted portion of the upper wafer W1 may also be greatly deformed, which can cause damage to the upper wafer W1 or the lower wafer W2.

The suction device 454 is connected to the control device 8, and performs a suction operation under the control of the control device 8. In a state where the contact member 452 is in contact with the non-bonding surface Win of the upper wafer W1, each attraction body 45 applies an attraction pressure from the suction device 454 to the contact member 452 via the suction path 453 and the cylindrical member 451 to attract the upper wafer W1.

In the example shown in FIG. 5, five attraction bodies 45 are provided in the support member 43. A pair of attraction bodies 45 is arranged in the X-axis direction via the fin 432 on the negative side of the Y-axis direction of the support member 43. Another pair of attraction bodies 45 is arranged in the X-axis direction via the through hole 433 on the through hole 433 side of the support member 43 (on the negative side of the Y-axis direction relative to the center of the support member 43). The remaining attraction body 45 is provided on the positive side of the Y-axis direction (adjacent to the fin 432 on the negative side of the Y-axis direction). However, the number and arrangement of attraction bodies 45 can be arbitrarily designed.

Further, as shown in FIG. 4, the upper attraction group 44 fixes a plurality of distance sensors 46 to the base member 41. The control device 8 can calculate a height (a position in the vertical direction) of the upper wafer W1 by measuring a distance from each distance sensor 46 to the combined wafer T (the upper wafer W1) facing the distance sensor 46. For example, the control device 8 can recognize a separation progress state by calculating the height of the upper wafer W1 in the separating operation.

The delivery holder 47 of the attraction separation device 40 is provided on the base member 41, and attracts the non-bonding surface Win of the separated upper wafer W1 held by the upper attraction group 44 to hold the upper wafer W1. The delivery holder 47 is equipped with a base member 471, a plurality of attraction pads 472, a plurality of contact pads 473, and a base member elevating mechanism 474 (one attraction pad 472 and one contact pad 473 illustrated in FIG. 4).

The base member 471 extends in the vertical direction, and has a cylindrical shape which is inserted through a through hole (not shown) the base member 41. The base member 471 supports the plurality of attraction pads 472 and the plurality of contact pads 473 on its lower end surface. The base member 471 is connected to the base member elevating mechanism 474 to be moved by the base member elevating mechanism 474 in the vertical direction. When the base member 471 is moved down, it passes through the through hole 433 of the support member 43.

The plurality of attraction pads 472 is formed of a rubber material or the like, and has, for example, a bellows shape. Thus, the plurality of attraction pads 472 can follow the displacement of the upper wafer W1 in the vertical direction and the horizontal direction. Each attraction pad 472 is connected to a suction device 476, such as a vacuum pump, via a suction path 475. The suction device 476 is connected to the control device 8, and performs a suction operation under the control of the control device 8. The delivery holder 47 applies an attraction pressure (negative pressure) to the plurality of attraction pads 472 via the suction path 475 and the base member 471 to attract the non-bonding surface W1n of the upper wafer W1.

Meanwhile, the plurality of contact pads 473 is formed of a resin material into a hemispherical shape, and is brought into contact with the non-bonding surface Win of the upper wafer W1 attracted by each attraction pad 472. The amount of protrusion of each contact pad 473 from the base member 471 can be adjusted by a non-illustrated adjustment unit, and each contact pad 473 assists in releasing the upper wafer W1 from the delivery holder 47.

The base member elevating mechanism 474 moves the base member 471 up and down under the control of the control device 8 and thus displaces the plurality of attraction pads 472 and the plurality of contact pads 473 in the vertical direction. For example, the base member elevating mechanism 474 moves the plurality of attraction pads 472 and the plurality of contact pads 473 up and down among a standby position, a hand-over position where the separated upper wafer W1 held by the upper attraction group 44 is attracted, and a delivery position where the upper wafer W1 is delivered to the second transfer device 6.

The pressing device 48 of the attraction separation device 40 is provided at an outer edge of the base member 41 (outside the pair of elevating mechanisms 42 in the radial direction), and presses down the dicing frame F in the vertical direction at an appropriate timing. For example, four pressing devices 48 are provided in the circumferential direction corresponding to the dicing frame F transferred to the holder 50. Also, the number of pressing devices 48 is not particularly limited.

Each pressing device 48 is equipped with a pressing pad 481, a shaft member 482, and a moving mechanism 483. The pressing pad 481 is formed of an elastic member, such as rubber. The shaft member 482 is supported by the moving mechanism 483 so as to be movable in the vertical direction and equipped with the pressing pad 481 on its lower end. The moving mechanism 483 is fixed to the base member 41 and also connected to the control device 8, and moves the shaft member 482 up and down under the control of the control device 8.

Meanwhile, the holder 50 of the separating apparatus 7 is provided from the middle to the bottom of the processing container 30 in the vertical direction, and attracts and holds the holding jig HJ that holds the combined wafer T. The holder 50 is equipped with a disc-shaped lower chuck 51, a column 52 configured to support the lower chuck 51, a rotary elevating mechanism 53 configured to rotate and elevate the lower chuck 51, and a frame holder 54 configured to hold the dicing frame F outside the lower chuck 51 in the radial direction.

The lower chuck 51 is formed of a metallic material, such as aluminum, and has the attraction surface 51s having a circular shape as its upper surface. The attraction surface 51s has a slightly greater diameter than the lower wafer W2. The attraction surface 51s is composed of an attraction pressure applying unit 511 made of a porous member, and has a flat shape without any grooves or holes. Thus, the lower chuck 51 applies the attraction pressure to the entire attraction surface 51s through the attraction pressure applying unit 511 to tightly attract the lower wafer W2. The attraction pressure applying unit 511 may be formed of a resin material, such as polychlorotrifluoroethylene (PCTFE).

A suction space 512 that communicates with the attraction pressure applying unit 511 is formed inside the lower chuck 51. A suction line 513 that communicates with the suction space 512 is connected to the outside of the lower chuck 51. The suction line 513 is connected to a suction path 514 equipped with a suction device 515, such as a vacuum pump. The holder 50 applies the attraction pressure to the attraction surface 51s from the suction device 515 via the suction path 514, the suction line 513, and the suction space 512.

When the combined wafer T is placed on the holder 50, a position of the combined wafer T is adjusted such that the center of the combined wafer T (the lower wafer W2) coincides with the center of the attraction surface 51s of the lower wafer W2. Also, the lower chuck 51 includes therein a plurality of lift pins (not shown), and moves each lift pin up and down relative to the attraction surface 51s to place the combined wafer T on the attraction surface 51s.

The rotary elevating mechanism 53 of the holder 50 can rotate the lower chuck 51 and displace the lower chuck 51 in a separation direction (vertical direction) perpendicular to an insertion direction of a blade 61. For example, the rotary elevating mechanism 53 includes therein a drive source configured to rotate the column 52, a drive source configured to move the column 52 up and down, and a delivery mechanism configured to deliver the driving force of each drive source (all not shown). The rotary elevating mechanism 53 is connected to the control device 8, and rotates the lower chuck 51 around the vertical axis under the control of the control device 8 and moves the lower chuck 51 up and down.

The frame holder 54 attracts the dicing frame F pressed by the pressing device 48 to hold the pressed dicing frame F. The frame holder 54 is equipped with a plurality of attraction pads 541 and a support body 542 configured to support the attraction pads 541. The attraction pads 541 are formed of an elastic member, such as rubber. For example, four attraction pads 541 are provided at an equal interval in the circumferential direction corresponding to the dicing frame F. For example, the attraction pads 541 may be provided to respectively face the plurality of pressing devices 48 in the vertical direction. Also, the number of attraction pads 541 is not particularly limited.

Each attraction pad 541 includes therein a non-illustrated suction port. Each attraction pad 541 is connected to a suction device 545, such as a vacuum pump, via the support body 542, a suction line 543 connected to the support body 542, and a suction path 544 connected to the suction line 543. An upper end (suction port) of the attraction pad 541 is located lower than the attraction surface 51s of the lower chuck 51 in the vertical direction. The suction device 545 is connected to the control device 8, and applies an attraction pressure to each attraction pad 541 under the control of the control device 8.

The support body 542 is supported by a lower base member 546, and protrudes at an appropriate position (in the circumferential direction corresponding to the dicing frame F) in the vertical direction to hold each attraction pad 541. The lower base member 546 has a circular plate shape, and fixes the support body 542 and the column 52. A non-illustrated rotational shaft of the rotary elevating mechanism 53 is connected to a lower surface of the lower base member 546.

Thus, the frame holder 54 may can attract and hold the dicing frame F by using a negative pressure generated by the suction of the suction device 545. Also, in the holder 50, the combined wafer T held by the lower chuck 51 and the dicing frame F held by the frame holder 54 can be displaced (rotated, elevated) integrally by the rotary elevating mechanism 53.

The separation inducing device 60 of the separating apparatus 7 is provided at a side of the attraction separation device 40 and the holder 50, and forms the groove portion CP inwardly from the outer edge of the combined wafer T in the radial direction when the upper wafer W1 and the lower wafer W2 of the combined wafer T are separated. The separation inducing device 60 is equipped with the blade 61, a blade slide mechanism 62, and a blade elevating mechanism 63.

The blade 61 is a separating member having an acute tip toward the positive Y-axis direction. The blade 61 has a rectangular shape that is short in the Y-axis direction and long in the X-axis direction when viewed from the top (see FIG. 5). A length of the blade 61 in the X-axis direction, i.e., a longitudinal length of the blade 61, may be set appropriately in a range of, for example, 50 mm to 150 mm. According to the exemplary embodiment, the longitudinal length of the blade 61 is set to 100 mm.

The blade slide mechanism 62 is equipped with a movable body 621 configured to support the blade 61 and a fixed body 622 configured to slidably support the movable body 621. The movable body 621 supports the blade 61 so as to protrude toward the positive Y-axis direction, and reciprocates in the Y-axis direction relative to the fixed body 622 based on driving of a non-illustrated drive source. That is, the blade 61 is advanced toward the positive Y-axis direction and retreated toward the negative Y-axis direction by the blade slide mechanism 62.

The blade elevating mechanism 63 is fixed to, for example, an end portion on the negative side of the Y-axis direction of the base member 41, and moves the blade slide mechanism 62 in the vertical direction. Thus, the separation inducing device 60 can adjust a height position of the blade 61.

For example, the separation inducing device 60 adjusts the height position of the blade 61 by using the blade elevating mechanism 63 and then advances the blade 61 in the positive Y-axis direction by using the blade slide mechanism 62. Along with the advancement of the blade 61, a tip of the blade 61 penetrates from a side of the combined wafer T to the adhesive G between the upper wafer W1 and the lower wafer W2 to form the groove portion CP between the upper wafer W1 and the lower wafer W2. The groove portion CP is formed by breaking the adhesive G adhering around the outer edge of the combined wafer T and separating the bonding surface W1j of the upper wafer W1 from the bonding surface W2j of the lower wafer W2.

### <Sequence of Separation of Combined Wafer T>

The separating apparatus 7 configured as described above performs the separation of the combined wafer T according to the sequence shown in FIG. 6A to FIG. 6D under the control of the control device 8.

Specifically, as shown in FIG. 6A, after the combined wafer T formed integrally with the dicing frame F is placed on the holder 50, the separating apparatus 7 applies the attraction pressure to the attraction surface 51s of the lower chuck 51 to fix the combined wafer T to the holder 50 via the dicing tape P. Further, the separating apparatus 7 moves the pressing device 48 vertically downwards to press the dicing frame F. In this case, the portion of the dicing tape P outside the lower chuck 51 is deformed diagonally downwards, which allows the displacement of the dicing frame F. Furthermore, the separating apparatus 7 operates the frame holder 54 to apply the attraction pressure to the attraction pads 541, and, thus, the pressed dicing frame F is held by the frame holder 54. Therefore, the side portion of the combined wafer T is located to face the blade 61 of the separation inducing device 60.

Then, as shown in FIG. 6B, the separating apparatus 7 performs a groove portion forming operation to form the groove portion CP by inserting the blade 61 of the separation inducing device 60 between the upper wafer W1 and the lower wafer W2 of the combined wafer T. Details of the groove portion forming operation will be described below.

Thereafter, as shown in FIG. 6C, the separating apparatus 7 moves the upper attraction group 44 down by using the pair of elevating mechanisms 42, and attracts the upper wafer W1 by using the respective attraction bodies 45. Also, the separating apparatus 7 raises the elevating mechanism 42 on the negative side of the Y-axis direction to bend the support member 43 on the negative side of the Y-axis direction. Therefore, the attraction body 45 on the negative side of the Y-axis direction is moved up to raise the upper wafer W1 on the negative side of the Y-axis direction, and, thus, a separating operation to separate the upper wafer W1 from the lower wafer W2 is started. Since the elevating mechanism 42 gradually moves up, the degree of bending of the support member 43 is gradually increased. Accordingly, the separation between the upper wafer W1 and the lower wafer W2 progresses from the negative side toward the positive side of the Y-axis direction.

When the separation between the upper wafer W1 and the lower wafer W2 progresses to a certain extent (e.g., when the separation progresses beyond the center of the combined wafer T), the separating apparatus 7 also raises the elevating mechanism 52 on the positive side of the Y-axis direction as shown in FIG. 6D to separate the upper wafer W1 from the lower wafer W2. As a bonding force between the upper wafer W1 and the lower wafer W2 becomes small in a late stage of the separating operation, the upper wafer W1 and the lower wafer W2 can be readily separated from each other.

As described above, the separating apparatus 7 can separate the upper wafer W1 and the lower wafer W2 by controlling the attraction separation device 40, the holder 50, and the separation inducing device 60.

Meanwhile, in a conventional separating apparatus, a single groove portion CP is formed at a position (a separation start position) on the negative side of the Y-axis direction by a separation inducing device, and then, the upper wafer W1 and the lower wafer W2 are separated from each other (see, for example, FIG. 7A). If the upper wafer W1 and the lower wafer W2 in the combined wafer T are tightly bonded to each other, a local stress is applied to the upper wafer W1 during the separating operation, which may cause the upper wafer W1 to be damaged (broken). Therefore, the separating apparatus 7 according to the exemplary embodiment is configured to promote the separation of the upper wafer W1 and the lower wafer W2 by forming the groove portions CP at different positions in the circumferential direction of the combined wafer T by using the separation inducing device 60. In other words, the separating apparatus 7 forms the groove portion CP having a circumferential length greater than the longitudinal length of the blade 61 of the separation inducing device 60. The expression “the groove portion CP having the circumferential length greater than the longitudinal length of the blade 61” may be implemented by a sum of circumferential lengths of a plurality of groove portions CP or by a circumferential length of a continuous groove portion CP.

### <Groove Portion Forming Operation>

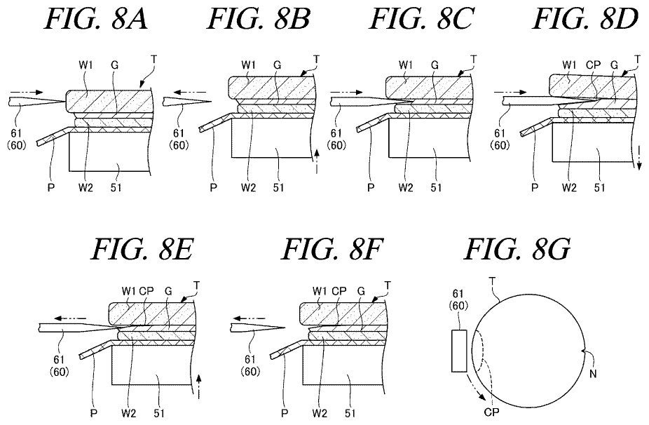

Hereinafter, the groove portion forming operation to form the plurality of groove portions CP will be described in detail with reference to FIG. 7A to FIG. 8G. During the groove portion forming operation to form the plurality of groove portions CP, an insertion operation to insert the blade 61 of the separation inducing device 60 is performed several times while changing a position in the circumferential direction of the combined wafer T.

A formation range of the groove portions CP is, for example, about 1/9 of the outer edge of the combined wafer T (approximately 40°, corresponding to about 105 mm in circumferential length) as shown in FIG. 7A. Therefore, when the insertion of the blade 61 of the separation inducing device 60 into the combined wafer T is performed once, about 8/9 of the outer edge of the combined wafer T (approximately 320°, corresponding to about 840 mm in circumferential length) remains in a state where the outer edge of the upper wafer W1 is bonded to the outer edge of the lower wafer W2. During the separating operation, the upper wafer W1 is likely to be cracked from a portion where the bonding force between the outer edge of the upper wafer W1 and the outer edge of the lower wafer W2 is strong.

Meanwhile, the separating apparatus 7 according to the exemplary embodiment forms a plurality of groove portions CP at the outer edge of the combined wafer T by inserting the blade 61 several times while changing a position in the circumferential direction of the combined wafer T. For example, as shown in FIG. 7B, the separating apparatus 7 can form nine groove portions CP in the entire circumference in the circumferential direction of the combined wafer T by performing the insertion operation nine times while changing the position in the circumferential direction of the combined wafer T with the rotary elevating mechanism 53 of the holder 50. Thus, before the separating operation, the separating apparatus 7 can eliminate (or reduce) the portion where the bonding force between the outer edge of the upper wafer W1 and the outer edge of the lower wafer W2 is strong in the entire circumference in the circumferential direction of the combined wafer T.

Specifically, when one round of insertion operation is performed, the separating apparatus 7 performs operations shown in FIG. 8A to FIG. 8F and also rotates the combined wafer T as shown in FIG. 8G. As shown in FIG. 8A, the separating apparatus 7 first advances the blade 61 toward the combined wafer T by using the blade slide mechanism 62 to bring the tip of the blade 61 into contact with the outer edge of the combined wafer T (the upper wafer W1) and thus detects the position of the outer edge of the combined wafer T. When the position of the outer edge of the combined wafer T is recognized, the control device 8 can adjust the actual insertion amount of the blade 61 into the adhesive G.

Thereafter, as shown in FIG. 8B, the separating apparatus 7 temporarily retreats the blade 61 to a side (in the negative Y-axis direction) from the combined wafer T by using the blade slide mechanism 62, and then, raises the combined wafer T by using the rotary elevating mechanism 53 of the holder 50. When the combined wafer T is raised, the control device 8 detects the height position of the upper wafer W1 by using the distance sensor 46 of the attraction separation device 40 and guides the upper wafer W1 to the target height position. Thus, the tip of the blade 61 faces the adhesive G of the combined wafer T. More specifically, the tip of the blade 61 faces the adhesive G near the bonding surface W1j of the upper wafer W1.

Then, as shown in FIG. 8C, the separating apparatus 7 advances the blade 61 in the positive Y-axis direction by using the blade slide mechanism 62 to insert the tip of the blade 61 into the adhesive G. The tip of the blade 61 is inserted near the bonding surface W1j of the upper wafer W1 depending on a facing position where the blade 61 faces the combined wafer T.

Thereafter, as shown in FIG. 8D, the separating apparatus 7 further advances the blade 61 and moves the lower chuck 51 vertically downward by using the rotary elevating mechanism 53 to lower the lower wafer W2 of the attracted combined wafer T together with the lower chuck 51. Herein, the amount of lowering of the lower wafer W2 is from about several hundred micrometers (μm) to about several millimeters (mm). As the lower wafer W2 is lowered, the outer edge of the upper wafer W1 and the outer edge of the lower wafer W2 can be greatly separated from each other. Thus, it is possible to increase the depth of the groove portion CP. Also, the outer edge of the upper wafer W1 is slightly mounted on an upper surface of the blade 61, which promotes the separation between the adhesive G and the upper wafer W1. Alternatively, after lowering the lower chuck 51, the separating apparatus 7 may further advance the blade 61 to increase the insertion amount of the blade 61. Otherwise, after further advancing the blade 61, the separating apparatus 7 may lower the lower chuck 51 by using the rotary elevating mechanism 53.

After advancing the blade 61 to a predetermined insertion amount, the separating apparatus 7, as shown in FIG. 8E, retreats the blade 61 by using the blade slide mechanism 62 and raises the lower wafer W2, which has been lowered as shown in FIG. 8D, by using the rotary elevating mechanism 53. Therefore, the outer edge of the upper wafer W1, which has been mounted on the blade 61, returns to its original position. However, since the groove portion CP formed between the adhesive G and the upper wafer W1 remains, the bonding force of the adhesive G at the groove portion CP is sufficiently reduced. Alternatively, after retreating the blade 61, the separating apparatus 7 may lower the lower chuck 51 by using the rotary elevating mechanism 53.

Then, as shown in FIG. 8F, the separating apparatus 7 retreats and separates the blade 61 from the combined wafer T. As a result, the separating apparatus 7 completes the one round of insertion operation.

Therefore, as shown in FIG. 8G, the separating apparatus 7 rotates the combined wafer T by a predetermined angle by using the rotary elevating mechanism 53 to allow the blade 61 to face a position different from the position where the groove portion CP is formed in the combined wafer T. For example, the rotary elevating mechanism 53 rotates the combined wafer T by 40° included in the formation range of the groove portions CP in the circumferential direction (counterclockwise in FIG. 7A and FIG. 7B) to allow the outer edge of the combined wafer T where a next groove portion CP is to be formed to face the blade 61. The separating apparatus 7 can form the next groove portion CP at the outer edge of the combined wafer T by performing the insertion operation again as shown in FIG. 8A to FIG. 8F.

The separating apparatus 7 can form the plurality of groove portions CP in the entire circumference in the circumferential direction of the combined wafer T by repeating nine times the operations shown in FIG. 8A to FIG. 8G. Thus, it is possible to reduce the bonding force at the outer edge of the combined wafer T. Therefore, during the separating operation after the groove portion forming operation, when the upper attraction group 44 pulls up the upper wafer W1 from the negative side of the Y-axis direction, the separating apparatus 7 can readily separate the upper wafer W1 from the lower wafer W2 in the positive Y-axis direction.

Also, during the insertion operation to insert the blade 61 by rotating the combined wafer T, the separating apparatus 7 may change the insertion amount of the blade 61 depending on the position in the circumferential direction of the combined wafer T. For example, the separating apparatus 7 may evaluate the combined wafer T in advance to identify a portion where the upper wafer W1 is likely to be cracked, and may increase the insertion amount of the blade 61 at the identified portion. Alternatively, for example, the separating apparatus 7 may increase the insertion amount of the blade 61 whenever the insertion operation is performed by rotating the combined wafer T.

### <Separating Method>

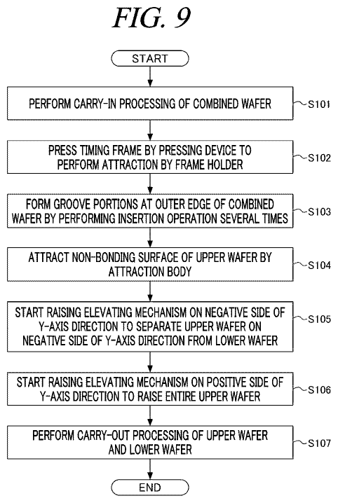

The separating apparatus 7 according to the exemplary embodiment is basically configured as described above, and the operation (separating method) thereof will be described below. The control device 8 controls, for example, processes S101 to S107 shown in FIG. 9 as the separating method of the separating apparatus 7.

The separating system 100 first performs a carry-in processing to carry the combined wafer T into the separating apparatus 7 (process S101). In the carry-in processing, the second transfer device 6 transfers the combined wafer T held by the dicing frame F and carries the combined wafer T into the processing container 30 of the separating apparatus 7 to align the center of the combined wafer T with the center of the attraction surface 51s of the lower chuck 51. Further, the separating apparatus 7 raises the lift pins from the attraction surface 51s to receive the combined wafer T, and lowers the lift pins to place the combined wafer T onto the attraction surface 51s. Along with the placement of the combined wafer T, the suction device 515 of the holder 50 performs the suction operation and fixes the combined wafer T (the dicing tape P) to the lower chuck 51.

Then, the separating apparatus 7 presses down the dicing frame F to the attraction pads 541 by using the pressing device 48, and attracts the pressed dicing frame F (including the dicing tape P) by using the frame holder 54 (process S102; see also FIG. 6A). Thus, the holder 50 can integrally secure the combined wafer T and the dicing frame F. Since the dicing frame F is pressed, the adhesive G between the upper wafer W1 and the lower wafer W2 in the combined wafer T is exposed laterally.

In this state, the separating apparatus 7 forms the groove portions CP at the different positions in the circumferential direction of the combined wafer T by performing the groove portion forming operation of the separation inducing device 60 (process S103; see also FIG. 6B). As described above with reference to FIG. 8A to FIG. 8F, during the groove portion forming operation according to the exemplary embodiment, the insertion operation is performed several times along the entire circumference in the circumferential direction of the combined wafer T while changing the position in the circumferential direction of the combined wafer T. Further, when the groove portions CP are formed, the attraction separation device 40 does not attract the upper wafer W1. Thus, when performing the insertion operation several times, the separating apparatus 7 can efficiently rotate the combined wafer T.

Desirably, the separation inducing device 60 may keep the blade 61 in the standby state during the separating operation without retreating the blade 61 from the portion where the last groove portion CP is formed. Thus, when the separating operation is started, the separating apparatus 7 can start separating the upper wafer W1 and the lower wafer W2 from the negative side of the Y-axis direction in the state where the upper wafer W1 is mounted on the blade 61.

Then, the separating apparatus 7 operates the pair of elevating mechanisms 42 to lower the plurality of attraction bodies 45 of the upper attraction group 44, and attract the non-bonding surface W1n of the upper wafer W1 by using the respective attraction bodies 45 (process S104). The attraction of the upper wafer W1 by the upper attraction group 44 may be performed before the process S103 to hold the upper wafer W1 during the groove portion forming operation.

Thereafter, the separating apparatus 7 proceeds to the separating operation, and raises the negative side of the Y-axis direction of the upper attraction group 44 to separate the upper wafer W1 from the lower wafer W2 on the negative side of the Y-axis direction (process S105). Specifically, the separating apparatus 7 raises the shaft 422 of the elevating mechanism 42 on the negative side of the Y-axis direction among the pair of elevating mechanisms 42 to raise the corresponding attraction body 45 on the negative side of the Y-axis direction (see FIG. 6C). As a result, the upper wafer W1 on the negative side of the Y-axis direction begins to be separated from the lower wafer W2. At this moment, a counterclockwise moment is produced on the upper wafer W1 as shown in FIG. 6C. Therefore, the upper attraction group 44 can raise the upper wafer W1 by pulling it upwards from the negative side of the Y-axis direction.

When the elevating mechanism 42 on the negative side of the Y-axis direction is raised to a certain extent, the separating apparatus 7 starts raising the elevating mechanism 42 on the positive side of the Y-axis direction to raise the entire upper wafer W1 (process S106, see FIG. 6D). At this process, the separation of the upper wafer W1 from the lower wafer W2 progresses beyond the center of the combined wafer T toward the positive side of the Y-axis direction. Therefore, the separating apparatus 7 can suppress damage to the upper wafer W1 while raising the upper wafer W1, and support the upper wafer W1 horizontally at the hand-over position.

Then, the separating system 100 proceeds to a carry-out processing to carry the separated upper wafer W1 and the separated lower wafer W2 out of the separating apparatus 7 (process S107). In the carry-out processing, the separating apparatus 7 returns the separation inducing device 60 to its initial position, and lowers the lower chuck 51. Thereafter, the separating apparatus 7 releases the attraction of the lower wafer W2 by the lower chuck 51 and the attraction by the frame holder 54, and raises the plurality of lift pins to lift the lower wafer W2 from the attraction surface 51s. The separating system 100 moves the second transfer device 6 to below the lower wafer W2, delivers the lower wafer W2 to the second transfer device 6 as the lift pins are lowered, and carries the lower wafer W2 out of the separating apparatus 7. Also, the separating apparatus 7 uses the delivery holder 47 to hold the upper wafer W1 held by the respective attraction bodies 45 of the upper attraction group 44 at the hand-over position. The separating system 100 attracts and holds the non-bonding surface W1n of the upper wafer W1 by using the second transfer device 6 which has been moved to vertically above the attraction pads 472 of the delivery holder 47, and carries the upper wafer W1 out of the separating apparatus 7 by using the second transfer device 6.

As described above, the separating apparatus 7 forms the groove portions CP to be longer than the longitudinal length of the blade 61 along the circumferential direction of the combined wafer T before the separating operation, and, thus, it is possible to reduce (or eliminate) the bonding force between the outer edge of the upper wafer W1 and the outer edge of the lower wafer W2. That is, the portion where the upper wafer W1 and lower wafer W2 are strongly bonded to each other is eliminated from the outer edge of the combined wafer T, and, thus, it is possible to suppress the damage to the upper wafer W1 or the lower wafer W2 from this portion during the separating operation. Particularly, the separating apparatus 7 can form the deep groove portions in the radial direction of the combined wafer T stably by forming the plurality of groove portions CP in the circumferential direction of the combined wafer T through the repeated insertion operations.

Further, during the insertion operation, the separating apparatus 7 displaces the lower wafer W2 in the separation direction (vertically downwards) by using the rotary elevating mechanism 53 and forms the deeper groove portion CP to separate the outer edge of the upper wafer W1 from the outer edge of the lower wafer W2. This ensures a more reliable reduction in the bonding force at the outer edge of the combined wafer T. Furthermore, after forming the groove portion CP, the separating apparatus 7 returns the upper wafer W1 and the lower wafer W2 to their original positions and retreats the blade 61 to facilitate the formation of the next groove portion CP. Also, the separating apparatus 7 can form the deeper groove portion CP at the portion with the strong bonding force by changing the insertion amount of the blade 61 at the different position in the circumferential direction of the combined wafer T. Thus, the separating apparatus 7 can perform the separation of the combined wafer T more stably.

The separating apparatus 7 can readily separate the upper wafer W1 from the lower wafer W2 by performing the separating operation to separate the upper wafer W1 from the lower wafer W2 by using the attraction separation device 40 after the groove portion forming operation. Particularly, the separation inducing device 60 keeps the blade 61 inserted between the upper wafer W1 and the lower wafer W2 at the start of the separating operation and thus can efficiently separate the upper wafer W1 from the lower wafer W2 when the separating operation is started.

Further, the separating apparatus 7 forms the groove portions CP in the entire circumference in the circumferential direction of the combined wafer T, and, thus, it is possible to reduce the bonding force in the entire outer edge of the combined wafer T.

The separating apparatus 7 according to the present disclosure is not limited to the above-described exemplary embodiments, and various modifications may be made. For example, the separating apparatus 7 may separate the upper wafer W1 and the lower wafer W2 while holding the combined wafer T, which does not include the dicing frame F and the dicing tape P, on the lower chuck 51. In this case, the separating apparatus 7 may not include the pressing device 48 and the frame holder 54.

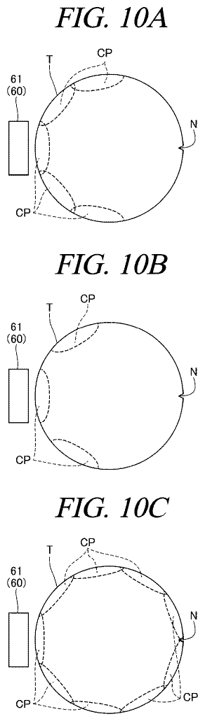

Also, as shown in FIG. 10A to FIG. 10C, the separating apparatus 7 may not form the groove portions CP in the entire circumference in the circumferential direction of the combined wafer T during the groove portion forming operation. For example, FIG. 10A illustrates a separating method according to a first modification example in which the groove portions CP are formed in the range from the negative side of the Y-axis direction to the middle of the combined wafer T in the Y-axis direction, but not from the middle to the positive side of the Y-axis direction. In this case, it is still possible to reduce the bonding force of the combined wafer T in the early stage of the separating operation, which is more prone to applying the greater forces to the upper wafer W1. Therefore, in the separating operation, it is possible to readily perform the separation while suppressing the damage to the upper wafer W1. Also, the separating apparatus 7 may not form the groove portion CP at the position where the notch N is formed, but form the groove portions CP at other positions.

FIG. 10B illustrates a separating method according to a second modification example in which the groove portions CP are formed at positions where the upper wafer W1 is likely to be cracked based on information of the positions previously acquired by experiment or simulation, but not at other positions. Therefore, according to this separating method, it is possible to more efficiently perform the groove portion forming operation and also possible to suppress the damage to the upper wafer W1 during the separating operation.

Also, FIG. 10C illustrates a separating method according to a third modification example in which the groove portions CP are formed without the operation of lowering the lower wafer W2 and mounting the upper wafer W1 on the blade 61 (see FIG. 8D) during the insertion operation. In this case, the groove portions CP are formed shallowly in the radial direction from the outer edge of the combined wafer T. However, it is possible to reduce the bonding force to a certain extent at the outer edge of the combined wafer T. Moreover, one round of insertion operation can be completed in a short time, and, thus, it is possible to efficiently perform the overall separating method even when a plurality of rounds of insertion operation is performed.

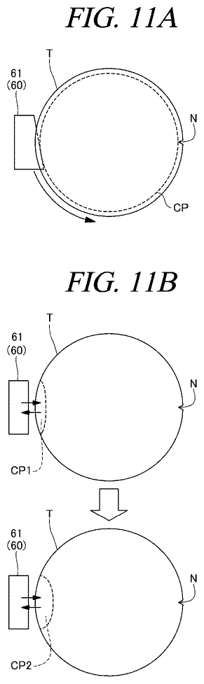

Further, in a fourth modification example as shown in FIG. 11A, the separating apparatus 7 may rotate the combined wafer T by using the rotary elevating mechanism 53 to change the position in the circumferential direction of the combined wafer T while keeping the blade 61 of the separation inducing device 60 inserted at the outer edge of the combined wafer T. Thus, the separating apparatus may form a continuous groove portion CP in the circumferential direction. Furthermore, in this case, the blade 61 of the separation inducing device 60 may have an obliquely inclined tip when viewed from the top. The separating apparatus 7 does not need to repeat the insertion operation to advance and retreat the blade 61, and, thus, it is possible to more efficiently reduce the bonding force at the outer edge of the combined wafer T.

Furthermore, in a fifth modification example as shown in FIG. 11B, when the portion with the strong bonding force is present at the outer edge of the combined wafer T, the separating apparatus 7 may advance (insert) and retreat the blade 61 several times at the same portion in the circumferential direction. For example, a shallow groove portion CP1 is formed during a first round of insertion operation as shown in the upper diagram of FIG. 11B, and a deep groove portion CP2 is formed during a second round of insertion operation as shown in the lower diagram of FIG. 11B. As a result, the separating apparatus 7 can reliably form the groove portions even where the upper wafer W1 and lower wafer W2 are strongly bonded to each other.

It should be noted that the separating method and the separating apparatus 7 according to the above-described exemplary embodiments are illustrative in all aspects and are not anyway limiting. The above-described exemplary embodiments can be modified and improved in various ways without departing from the scope and the spirit of claims. Unless contradictory, other configurations may be adopted, and the disclosures in the various exemplary embodiments can be combined appropriately.

According to the exemplary embodiment, it is possible to suppress the damage to the substrate when separating the combined substrate.

From the foregoing, it will be appreciated that various exemplary embodiments of the present disclosure have been described herein for purposes of illustration and various changes can be made without departing from the scope and spirit of the present disclosure. Accordingly, various exemplary embodiments described herein are not intended to be limiting, and the true scope and spirit are indicated by the following claims.

We claim:

1. A separating apparatus, comprising:
a holder for holding a combined substrate and rotating the combined substrate in a circumferential direction, the combined substrate including a first substrate bonded to a second substrate;
a separation inducing device including a blade, the separation inducing device being for forming a groove portion in the combined substrate by inserting the blade between the first substrate and the second substrate from a side of the combined substrate held by the holder; and
control circuitry configured to control the holder and the separation inducing device to form the groove portion longer than a longitudinal length of the blade along the circumferential direction of the combined substrate.

2. The separating apparatus of claim 1,
wherein the groove portion includes multiple groove portions, and
the control circuitry is configured to control the separation inducing device to insert the blade into the combined substrate several times while controlling the holder to change a position of the combined substrate in the circumferential direction of the combined substrate to form the multiple groove portions.

3. The separating apparatus of claim 2,
wherein the holder is configured to displace the combined substrate held thereon in a separation direction perpendicular to an insertion direction of the blade, and
the control circuitry is configured to control the holder to move in the separation direction to separate the first substrate and the second substrate while controlling the separation inducing device to keep the blade inserted between the first substrate and the second substrate of the combined substrate.

4. The separating apparatus of claim 3,
wherein after forming the multiple groove portions, the control circuitry is configured to control the holder to return the first substrate and the second substrate to their original positions and control the separation inducing device to retreat the blade.

5. The separating apparatus of claim 2,
wherein the control circuitry configured to control the separation inducing device to change an insertion amount of the blade at a different position in the circumferential direction of the combined substrate.

6. The separating apparatus of claim 1,
wherein the control circuitry is configured to control the holder to change a position in the circumferential direction of the combined substrate while controlling the separation inducing device to keep the blade inserted into the combined substrate to form a continuous groove portion in the circumferential direction.

7. The separating apparatus of claim 1, further comprising:
an attraction separator configured to attract the first substrate of the combined substrate held by the holder,
wherein after forming the groove portion longer than the longitudinal length of the blade, the control circuitry controls the attraction separator to perform a separating operation to separate the first substrate from the second substrate.

8. The separating apparatus of claim 7,
wherein the control circuitry is configured to control the attraction separator to perform the separating operation to separate the first substrate from a direction where the blade is disposed toward an opposite side to the combined substrate, and
the control circuitry is configured to control the separation inducing device to keep the blade inserted between the first substrate and the second substrate when the separating operation is started.

9. The separating apparatus of claim 7,
wherein the control circuitry is configured to control the attraction separator to not attract the first substrate when the groove portion is formed.

10. The separating apparatus of claim 1,
wherein the control circuitry is configured to control the separation inducing device to form the groove portion in an entire circumference in the circumferential direction of the combined substrate.

11. The separating apparatus of claim 1, further comprising:
a dicing frame for receiving the combined substrate;
dicing tape for fixing the combined substrate to the dicing frame;
a pressing device for pressing the dicing frame; and
a frame holder for holding the pressed dicing frame,
wherein the control circuitry is configured to control the separation inducing device to form the groove portion while the dicing frame is held by the frame holder.

12. A separating method, comprising:
holding a combined substrate by a holder which is configured to be rotated in a circumferential direction, the combined substrate including a first substrate bonded to a second substrate; and
forming a groove portion in the combined substrate by inserting a blade of a separation inducing device between the first substrate and the second substrate from a side of the combined substrate held by the holder, after the holding of the combined substrate,
wherein in the forming of the groove portion, control circuitry controls the holder and the separation inducing device to form the groove portion longer than a longitudinal length of the blade along the circumferential direction of the combined substrate.

13. The separating method of claim 12, further comprising:
separating, after the forming of the groove portion, the first substrate from the second substrate by an attraction separator while the combined substrate is held by the holder.

14. The separating method of claim 12, wherein the groove portion includes multiple groove portions, and
wherein the groove portion is formed by inserting the blade into the combined substrate several times while the holder changes a position of the combined substrate in the circumferential direction of the combined substrate to form the multiple groove portions.

15. The separating method of claim 14, further comprising:
displacing, by the holder, the combined substrate held thereon in a separation direction perpendicular to an insertion direction of the blade, and
moving the holder in the separation direction to separate the first substrate and the second substrate while the separation inducing device keeps the blade inserted between the first substrate and the second substrate.

16. The separating method of claim 15, further comprising:
after forming the multiple groove portions, returning, by the holder, the first substrate and the second substrate to their original positions and retreating the blade.

17. The separating method of claim 14, further comprising:
changing an insertion amount of the blade at a different position in the circumferential direction of the combined substrate.

18. The separating method of claim 12, further comprising:
changing, by holder, a position in the circumferential direction of the combined substrate while the separation inducing device keeps the blade inserted into the combined substrate to form a continuous groove portion in the circumferential direction.

19. The separating method of claim 12, further comprising:
attracting, by an attraction separator, the first substrate of the combined substrate held by the holder; and
after forming the groove portion longer than the longitudinal length of the blade, performing, by the attraction separator, a separating operation to separate the first substrate from the second substrate.

20. The separating method of claim 19, wherein:
the attraction separator performs the separating operation to separate the first substrate from a direction where the blade is disposed toward an opposite side to the combined substrate, and
the separation inducing device keeps the blade inserted between the first substrate and the second substrate when the separating operation is started.
